(19) United States
(12) Patent Application Publication
(10) Pub. No.: US 2012/0118384 A1
(43) Pub. Date: May 17, 2012

(54) CIS-BASED THIN FILM SOLAR CELL

(75) Inventors: Hideki Hakuma, Tokyo (JP); Hiroki Sugimoto, Tokyo (JP); Shunsuke Kijima, Tokyo (JP); Yoshiaki Tanaka, Tokyo (JP)

(73) Assignee: SHOWA SHELL SEKIYU K.K., Tokyo (JP)

(21) Appl. No.: 13/379,871

(22) PCT Filed: Jun. 18, 2010
(86) PCT No.: PCT/JP2010/060793

§ 371 Date: Dec. 21, 2011

(30) Foreign Application Priority Data
Jun. 23, 2009 (JP) 2009-148768

(51) Int. Cl. H01L 31/0264; H01L 31/02

(52) U.S. Cl. 136/262; 136/252

(57) ABSTRACT

In order to provide a CIS-based thin film solar cell having high photoelectric conversion efficiency, this CIS-based thin film solar cell is laminated in order of a high distortion point glass substrate (1), an alkali control layer (2), a back electrode layer (3), a p-type CIS-based light absorbing layer (4), and an n-type transparent conductive film (6), wherein said alkali control layer (2) is a silica film whose film thickness is within a range of 2.00-10.00 nm and whose refractive index is within a range of 1.450-1.500.

### REFERENCE TO RELATED APPLICATIONS

This application is the national stage under 35 USC 371 of International Application No. PCT/JP2010/060793, filed Jun. 18, 2010, which claims the priority of Japanese Patent Application No. 2009-148768, filed Jun. 23, 2009, the entire contents of which are incorporated herein by reference.

### TECHNICAL FIELD

The present invention relates to a CIS-based thin film solar cell and, in particular, relates to a CIS-based thin film solar cell having a novel structure that can achieve high photoelectric conversion efficiency.

### BACKGROUND ART

In recent years, a CIS-based thin film solar cell that uses a chalcopyrite structure I-III-VI₂ group compound semiconductor containing Cu, In, Ga, Se and S as a p-type light absorbing layer has been attracting attention. A solar cell of this type can be manufactured at relatively low cost. Moreover, because a solar cell of this type has a large absorption coefficient in a wavelength range from visible light to near-infrared light, it is anticipated that high photoelectric conversion efficiency can be attained. It is, therefore, widely considered as a leading candidate for the next-generation solar cell. Typical materials include Cu(In, Ga) Seₑ, Cu(In, Ga) (Se, S)₂, CuInS₂ and so on.

In the CIS-based thin film solar cell, a metal back electrode layer is formed on a glass substrate. Then, a p-type light absorbing layer comprised of the I-III-VI₂ group compound semiconductor is formed on this layer and, further, an n-type buffer layer and an n-type transparent conductive window layer are formed. In this CIS-based thin film solar cell, it is reported that high photoelectric conversion efficiency can be achieved when a soda lime glass is used as the glass substrate.

It is thought that this is because Na, or a Ia group element contained in the soda lime glass is thermal-diffused into the p-type light absorbing layer in the formation process of this layer and affects carrier concentration. On the other hand, there is a problem that, when the amount of Na introduced into the p-type light absorbing layer is too high, the p-type light absorbing layer may be separated from the electrode layer. When the CIS-based thin film solar cell is manufactured, it is, therefore, very important to introduce an optimal amount of Na into the p-type light absorbing layer so as to improve its photoelectric conversion efficiency.

In order to introduce an optimal amount of the Ia group element such as, for example, Na contained in the soda lime glass into the p-type light absorbing layer during the film forming process of this layer, a technique in which an alkali control layer made of silica and the like between the soda lime glass substrate and the back electrode layer is provided so as to control the amount of Na diffused into the p-type light absorbing layer has been proposed. (For example, see Japanese Unexamined Patent Publication No. 2006-165386.) According to this technique, the present inventors have succeeded in manufacturing a CIS-based thin film solar cell having a photoelectric conversion efficiency of 14.3% by using an alkali control layer having a thickness of 30 nm.

On the other hand, in order to improve the photoelectric conversion efficiency of the CIS-based thin film solar cell, it is necessary to increase the film forming temperature of the p-type light absorbing layer or the temperature of sulfurization/selenization. However, the soda lime glass has a relatively low distortion point. If the p-type light absorbing layer is formed at a higher film forming temperature such as, for example, at 550° C. or higher in order to further improve the photoelectric conversion efficiency, the soda lime glass substrate is therefore deformed. Thus, on the soda lime glass substrate, the film forming temperature of the p-type light absorbing layer cannot be sufficiently increased. In order to form the p-type light absorbing layer at a sufficiently high temperature, the glass substrate has to be made of high distortion point glass that is low alkali or non-alkali glass. However, because these glass materials contain too low a concentration of the alkali components or do not contain them at all, the p-type light absorbing layer cannot be supplied with sufficient alkali components.

Also in the prior art, Japanese Unexamined Patent Publication No. H11-135819 discloses a technique in which high distortion point glass as the substrate of the CIS-based thin film solar cell is used. However, in this patent publication, it is considered important to inhibit deformation of the glass substrate due to heat history and distortion due to a difference in thermal expansion coefficient between the substrate and the CIS-based semiconductor layers by using the high distortion glass as the substrate, so that the CIS-based thin film solar cell can be manufactured inexpensively. This prior art does not, therefore, take in account improving photoelectric conversion efficiency due to the optimal diffusion of Na from the glass substrate and the solar cell according to this prior art is not provided with the alkali control layer.

### SUMMARY OF THE INVENTION

The present invention has been made to solve the above problems of a CIS-based thin film solar cell and to obtain a CIS-based thin film solar cell that has higher photoelectric conversion efficiency. Thus, it is an object of the present invention to provide a CIS-based thin film solar cell having a novel structure that can introduce an optimal amount of a Ia group element, such as Na into a p-type light absorbing layer, even when a glass substrate is made of high distortion point glass in place of soda lime glass having a low distortion point.

In order to solve the above problems, according to an embodiment of the present invention, a CIS-based thin film solar cell laminated in order to produce a high distortion point glass substrate, an alkali control layer, a back electrode layer, a p-type CIS-based light absorbing layer, and an n-type transparent conductive film, wherein said alkali control layer is a silica film whose film thickness is within a range of 2.00-10.00 nm and whose refractive index is within a range of 1.450-1.500 is provided.

In the CIS-based thin film solar cell, the film thickness of the alkali control layer may be within a range of 2.00-7.00 nm. Further, the refractive index of the alkali control layer may be within a range of 1.470-1.490.

Further, in the CIS-based thin film solar cell, a distortion point of the high distortion point glass substrate may be 560° C. or higher. Further, the annealing point may be 610° C. or higher. Further, the thermal expansion coefficient may be within a range of 8×10⁻⁶/° C.-9×10⁻⁶/° C. Moreover, the density may be within a range of 2.7-2.9 g/cm³.

In the CIS-based thin film solar cell, the high distortion point glass may contain 1-7 weight % of Na₂O. In particular, the high distortion point glass may contain 3-5 weight % of Na₂O. Further, the high distortion point glass may contain 1-15 weight % or, in particular, 5-10 weight % of K₂O. Moreover, the high distortion point glass may contain 1-15 weight % or, in particular, 4-10 weight % of CaO.

Further, the p-type CIS-based light absorbing layer may be formed of a five component compound that is mainly comprised of Cu, In, Ga, Se and S. Further, the p-type CIS-based light absorbing layer may be formed by selenizing and sulfurizing a laminated structure containing Cu, In and Ga or a mixed crystal.

According to the present invention, the alkali control layer that is a silica film having a film thickness within a range of 2.00-10.00 nm and a refractive index within a range of 1.450-1.500 is provided between the high distortion point glass substrate and the back electrode. The alkali control layer of this structure can efficiently diffuse an alkali element of a low concentration contained in the high distortion point glass into the p-type light absorbing layer. As a result, by forming the p-type light absorbing layer at a high temperature such as, for example, 600° C. or more, the CIS-based thin film solar cell having high photoelectric conversion efficiency can be implemented.

### BRIEF DESCRIPTION OF THE DRAWINGS

FIG. 1 is a schematic cross-sectional view illustrating a structure of a conventional CIS-based thin film solar cell;

FIG. 2 is a schematic cross-sectional view illustrating a structure of a CIS-based thin film solar cell according to an embodiment of the present invention;

FIG. 3 is a table indicating measurement values of film thickness, refractive index and photoelectric conversion efficiency of an alkali control layer in a plurality of CIS-based thin film solar cell;

FIG. 4 is a graph indicating a relationship between the film thickness and the photoelectric conversion efficiency of the alkali control layer, taken out from the data of FIG. 3;

FIG. 5 is a graph indicating a part of the graph of FIG. 4 in detail; and

FIG. 6 is a graph indicating a relationship between the refractive index and the photoelectric conversion efficiency of the alkali control layer, taken out from the data of FIG. 3.

### DETAILED DESCRIPTION OF THE INVENTION

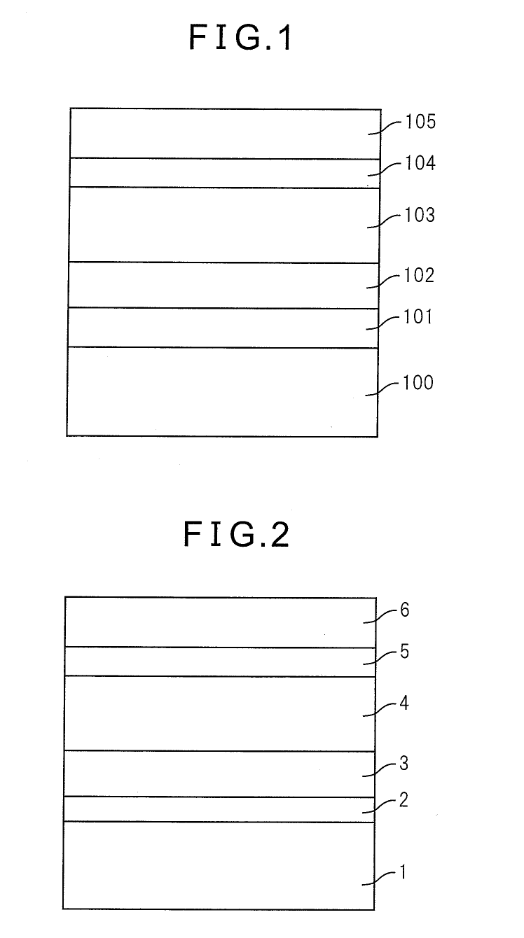

In comparison with the present invention, FIG. 1 illustrates a structure of a conventional CIS-based thin film solar cell having an alkali control layer. FIG. 1 illustrates a soda lime glass substrate 100 containing 12-15 weight % of Na₂O, and a alkali control layer 101 comprised of silica (SiOₓ) and the like. This alkali control layer has a film thickness of about 30 nm and quality or, for example, refractive index of the film is not taken into consideration. FIG. 1 further illustrates a back electrode layer 102 made of Mo and the like, a p-type light absorbing layer 103 formed of a CIS-based semiconductor, a buffer layer 104, and an n-type window layer 105 (transparent conductive film). Due to heat treatment during formation of p-type light absorbing layer 103 on back electrode layer 102, Na contained in the soda lime glass substrate is diffused into the p-type light absorbing layer. Alkali control layer 101 is intended to control the amount of diffusion of Na element into p-type light absorbing layer 103. In experiments carried out by the inventors, etc., when alkali control layer 101 is formed of silica having a thickness of about 30 nm, the maximum photoelectric conversion efficiency of 14.3% could be achieved.

FIG. 2 illustrates a structure of a CIS-based thin film solar cell according to an embodiment of the present invention. FIG. 2 illustrates a high distortion point glass substrate 1 containing 3-5 weight % of Na₂O, and an alkali control layer 2 that is made of silica (SiO₂) and that has a film thickness within a range of 4-5 nm and a refractive index within a range of 1.47-1.48. This refractive index is measured with light of a wavelength of 633 nm. FIG. 2 further illustrates a back electrode layer 3 made of Mo, a p-type light absorbing layer 4 comprised of the CIS-based semiconductor, a buffer layer 5, and a window layer 6 formed of an n-type transparent conductive film.

Table 1 indicates physical properties of high distortion point glass substrate 1 of this embodiment.

TABLE 1
Physical Properties of High Distortion Point Glass Substrate

| | |
|---|---|
| Distortion point | 560° C. or more |
| Annealing point | 610° C. or more |
| Thermal expansion coefficient | 8 × 10⁻⁶/° C.-9 × 10⁻⁶/° C. |
| Na₂O content | 3-5 weight % |
| K₂O content | 5-10 weight % |
| CaO content | 1-10 weight % |

The contents of Na₂O, K₂O and CaO in the high distortion point glass used in this embodiment are as indicated in Table 1. Typical high distortion point glass contains 1-7 weight % of Na₂O, 1-15 weight % of K₂O and 1-15 weight % of CaO and the high distortion point glass like this can also be used to constitute the CIS-based thin film solar cell according to the present invention. Further, there is a high distortion point glass that does not satisfy the above conditions and even such glass may be used to manufacture the solar cell of the present invention.

Next, a film forming method for alkali control layer 2 will be described. Alkali control layer 2 can be formed, for example, by using SiOₓ or Si as a target with the help of 1) RF sputtering method, 2) AC sputtering method or 3) DC sputtering method. In the film forming method using these sputtering methods, the alkali control layer having various film thickness and refractive index can be formed by changing parameters such as applied electric power, O₂ concentration and film forming pressure. The parameters may include gas flow rate, substrate carrying speed and the like.

An example of the parameters is as follows:

RF sputtering: SiO₂ target

Applied electric power: 0.1-3 W/cm²

O₂ concentration (O₂/O₂+Ar): 0-20%

Film formation pressure: 0.3-2.0 Pa

In place of the sputtering methods described above, alkali control layer 2 can also be formed by plasma CVD method, electron beam evaporation method and the like.

Table 2 indicates a construction of back electrode 3.

TABLE 2
Construction of Back Electrode

| | |
|---|---|
| Film thickness | 200-500 nm |
| Film forming method | DC sputtering |
| | Film forming pressure: 1.0-2.5 Pa |
| | Applied electric power: 1.0-3.0 W/cm² |

Next, p-type light absorbing layer 4 will be described in detail.

In order to form p-type light absorbing layer 4, a metal precursor film of a laminated structure or a mixed crystal containing Cu, In and Ga is formed on metal back electrode 3 by the sputtering or evaporation method and, then, selenized and sulfurized. In this example, when a ratio of atomicity of Cu to III group element or In and Ga (Cu/III group ratio) is fixed to 0.85-0.95 and a ratio of atomicity of Ga in III group element (Ga/III group ratio) is fixed to 0.15-0.4, the selenization is performed at 350° C.-500° C. and the sulfurization is performed at 550° C.-650° C., so that a light absorbing layer of a film thickness of 1-3 μm having p-type electrical conduction can be formed.

In the embodiment of FIG. 2, as p-type light absorbing layer 4, a film of copper indium gallium di-selenide/sulfide (Cu(InGa)(SeS)₂) is formed. However, the present invention is not limited to this embodiment and p-type light absorbing layer 4 may be formed of any I-III-VI₂ group chalcopyrite semiconductor, for example, such as:

cooper indium di-selenide (CuInSe₂);

cooper indium di-sulfide (CuInS₂);

cooper indium di-selenide/sulfide (CuIn(SeS)₂);

cooper gallium di-selenide (CuGaSe₂);

cooper gallium di-sulfide (CuGaS₂);

copper indium gallium di-selenide (Cu(InGa)Se₂); and

copper indium gallium di-sulfide (Cu(InGa)S₂).

Next, buffer layer 5 will be described in detail.

In the embodiment of FIG. 2, as buffer layer 5, a film of transparent and high resistance Zn (O, S, OH)ₓ of a film thickness of 2-50 nm having n-type electrical conduction is formed. This buffer layer 5 can be formed by chemical bath deposition method or MOCVD method. In this embodiment, as buffer layer 5, a semiconductor film comprised of Zn (O, S, OH)ₓ is formed. However, the present invention is not limited to this embodiment. For example, buffer layer 5 may be formed of a II-VI group compound semiconductor thin film such as, for example, CdS, ZnS and ZnO and their mixed crystal such as Zn(O, S)ₓ and an In based compound semiconductor thin film such as, for example, In₂O₃, In₂S₃ and In(OH).

Next, window layer (transparent conductive film) 6 will be described in detail.

In the embodiment of FIG. 2, a transparent low-resistance semiconductor film of a thickness of 0.5-2.5 μm that is comprised of ZnO:B and that has n-type electrical conduction and a wide band gap is formed. This window layer 6 can be formed by the sputtering method or the MOCVD method. In place of ZnO:B used in this embodiment, ZnO:Al and ZnO:Ga can be used as window layer 6. Further, window layer 6 may be a semiconductor film comprised of a transparent conductive film (ITO).

In the CIS-based thin film solar cell according to the embodiment of the present invention illustrated in FIG. 2, the present inventors could achieve the maximum photoelectric conversion efficiency of 15.3%. In comparison with the fact that the maximum photoelectric conversion efficiency of the conventional CIS-based thin film solar cell illustrated in FIG. 1 is 14.3%, the present invention exhibits a remarkable improvement in the photoelectric conversion efficiency. Table 3 summarizes the difference of the structure and properties of the CIS-based thin film solar cell between FIG. 1 (the conventional art” and FIG. 2 (the present invention):

TABLE 3
Comparison with the Conventional Art

| | | | CIS-based thin | |
|---|---|---|---|---|
| | CIS-based thin | | film solar cell | |
| | film solar cell | | according to an | |
| | according to the | | embodiment of the | |
| | conventional art | | present invention | |
| Na₂O content in | 12-15 | weight % | 3-5 | weight % |
| glass substrate | | | | |
| Alkali control layer | 30 | nm | 4-5 | nm |
| film thickness | | | | |

| | | |
|---|---|---|
| Alkali control layer | not specified | refractive index: |
| quality | | 1.47-1.48 |
| Maximum photoelectric | 14.3% | 15.3% |
| conversion efficiency | | |

The values of the film thickness and refractive index of the alkali control layer indicated in Table 3 are merely fixed according to an embodiment of the present invention and the present invention is not limited to this embodiment. According to the present invention, the alkali control layer desirably has a film thickness of 2-10 nm and a refractive index of 1.45-1.50 (at a wavelength of 633 nm) and, more desirably, it has a film thickness of 2-7 nm and a refractive index of 1.47-1.49.

Hereinafter, results of an experiment carried out to determine the above structure of the CIS-based thin film solar cell according to the present invention will be described.

The high distortion point glass typically contains 1-7 weight % of Na₂O, 1-15 weight % of K₂O and 1-10 weight % of CaO. The Na content in the high distortion point glass is about half or less than that in the soda lime glass. However, the present inventors believe that, if these elements could be efficiently diffused into the p-type light absorbing layer by optimizing the structural and physical properties of the alkali control layer, with the help of high temperature treatment making use of the properties of the high distortion point glass, the CIS-based thin film solar cell having high photoelectric conversion efficiency could be obtained. In CIS-based thin film solar cells whose alkali control layer was composed of silica (SiOₓ), the film thickness was selected as a structural factor and the refractive index was selected as a physical factor. Then, changing these factors variously, the present inventors measured the photoelectric conversion efficiency. In this experiment, a plurality of CIS-based thin film solar cells whose film thickness was within a range of 0-30 nm and whose refractive index was within a range of 1.407-1.507 could be obtained. This refractive index was a value measured at a wavelength of 633 nm.

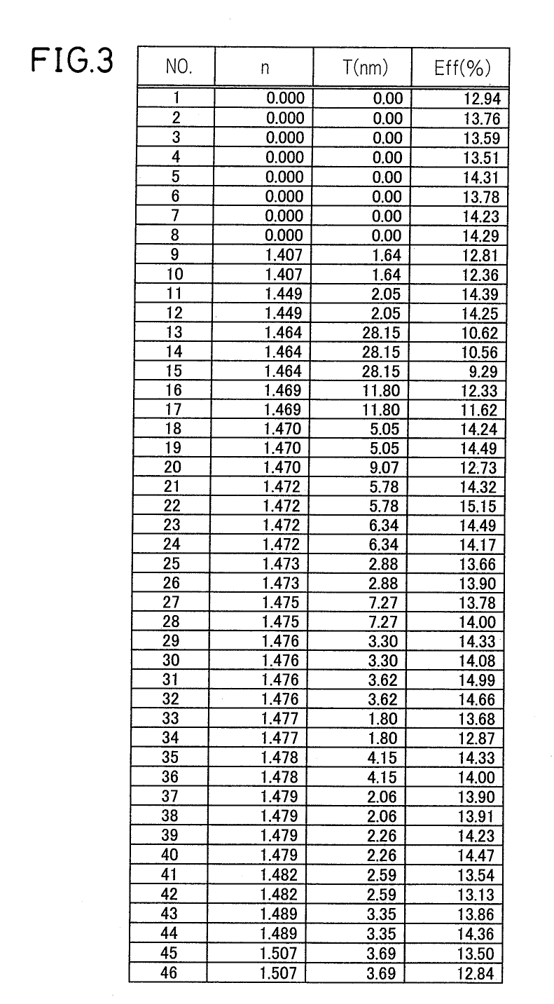

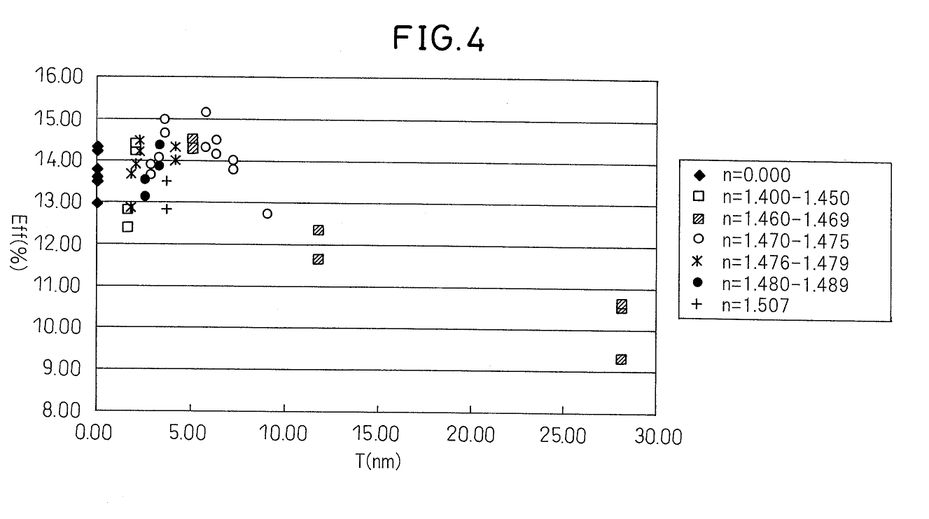

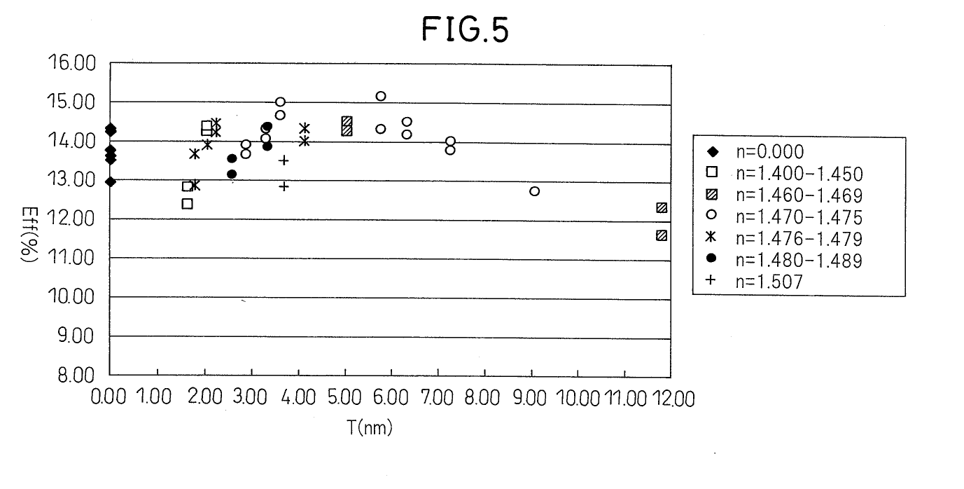

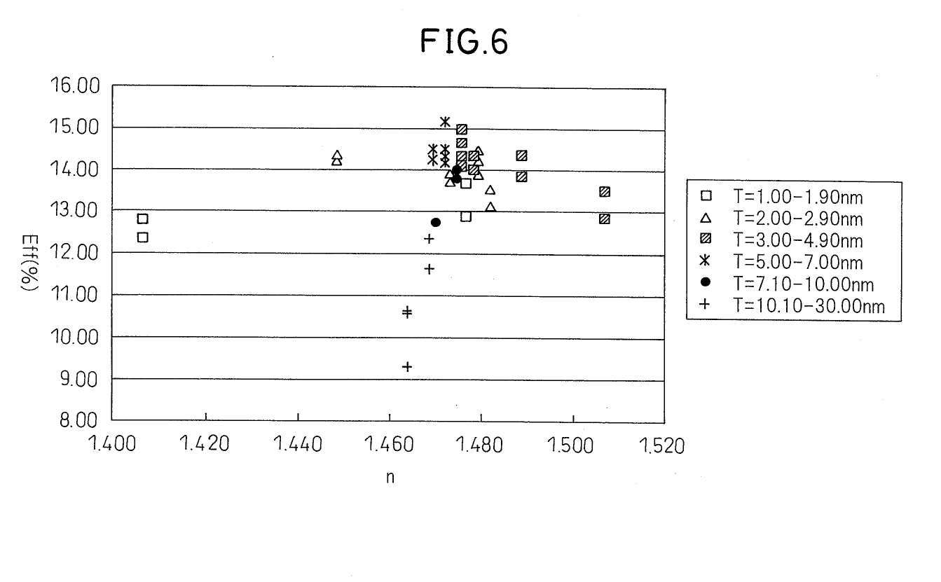

FIG. 3 indicates measurement data in the CIS-based thin film solar cells illustrated in FIG. 2. FIGS. 4 and 5 indicate the measurement data arranged as graphs of film thickness/photoelectric conversion efficiency. FIG. 6 indicates the measurement data arranged as graphs of refractive index/photoelectric conversion efficiency. First, the data table indicated in FIG. 3 will described. This table lists the CIS-based thin film solar cells of sample number (No.) 1-46 with film thickness T (nm) of alkali control layer 2, refractive index n and photoelectric conversion efficiency Eff (%) in 30 minutes after light irradiation.

As indicated in FIG. 3, in the CIS-based thin film solar cells of sample number 9-46 (hereinafter referred to as the samples), when alkali control layer 2 is formed by the RF sputtering method, the film thickness and refractive index of the alkali control layer were changed by changing the applied electric power, gas concentration (the ratio of O₂ to argon) and film forming pressure described above. Further, for the purpose of comparison, in the samples of sample number 1-8, the data (photoelectric conversion efficiency) of the samples that do not have alkali control layer 2 are indicated. In the samples of sample number 1-46, the structure (film thickness) and refractive index of the alkali control layer are changed but other conditions such as, for example, the structure and manufacturing process of high distortion point glass 1, back electrode layer 3, p-type light absorbing layer 4, buffer layer 5 and transparent conductive film 6 are identical.

FIGS. 4 and 5 are graphs based on the data indicated in FIG. 3, in which the horizontal axis indicates the film thickness T in nm of the alkali control layer and the vertical axis indicates the photoelectric conversion efficiency (Eff) in % and the refractive index n of the alkali control layer is grouped into a plurality of levels and plotted. Then, FIG. 6 is a graph based on the data indicated in FIG. 3, in which the horizontal axis indicates the refractive index n (at a wavelength of 633 nm) and the vertical axis indicates the photoelectric conversion efficiency (Eff) in %.

From the graphs in FIGS. 4 and 5, the following facts will be understood. When the film thickness T of the alkali control layer exceeds 10 nm, the photoelectric conversion efficiency is reduced remarkably and it is therefore desirable that the film thickness T of the alkali control layer is 10 nm or less. On the other hand, when the film thickness T of the alkali control layer is 2 nm or less, the photoelectric conversion efficiency of some samples is 12.5% or less and it is therefore desirable that the film thickness T of the alkali control layer is 2 nm or more. Referring to FIG. 5 in more detail, the samples whose alkali control layer has a film thickness T within a range of 2 nm-7 nm have a photoelectric conversion efficiency larger than 13%, with the exceptions of the samples whose refractive index is 1.50 or more. As a result, it is more desirable that the film thickness T of the alkali control layer is within a range of 2 nm-7 nm. Although some samples that do not have the alkali control layer have a photoelectric conversion efficiency higher than 14%, it is assumed that the present invention has an alkali control layer. This is because, in addition to the problem of the photoelectric conversion efficiency, the samples that do not have the alkali control layer have a problem of reliability in that the layers formed on the glass substrate are likely to be separated from the glass substrate.

Next, from the graph of FIG. 6, the following facts will be understood. Thus, even in the CIS-based thin film solar cells whose film thickness T of the alkali control layer is within a range of 2-10 nm, when the refractive index n of the alkali control layer exceeds 1.50, the photoelectric conversion efficiency Eff is reduced. This is because the diffusion of the alkali control layer from the high distortion point glass cannot be controlled by the film thickness control of the alkali control layer only. The diffusion of the alkali control layer from the high distortion point glass can be controlled only when both the film thickness T and quality (determined through the refractive index) of the alkali control layer are controlled. Further, from the graph of FIG. 6, when the refractive index n of the alkali control layer is 1.45 or more, samples having good photoelectric conversion efficiency can be obtained. As a result, by providing the alkali control layer having a film thickness T within a range of 2.00-10.00 nm and a refractive index n within a range of 1.450-1.500, the photoelectric conversion efficiency Eff of the CIS-based thin film solar cell can be improved. Further, referring to FIG. 6 in more detail, it is to be noted that the samples having a film thickness T within a range of 2.00-7.00 nm and a refractive index n within a range of 1.470-1.490 have better photoelectric conversion efficiency.

As a result, the present inventors have reached the conclusion that, when the high distortion point glass is used as the glass substrate, in the case of the film thickness T of the alkali control layer within a range of 2.00-10.00 nm and the refractive index n within a range of 1.450-1.500, a good CIS-based thin film solar cell having high photoelectric efficiency can be obtained and, more preferably, in the case of the film thickness T of the alkali control layer within a range of 2.00-7.00 nm and the refractive index n within a range of 1.470-1.490, a CIS-based thin film solar cell having higher photoelectric efficiency can be obtained.

1. A CIS-based thin film solar cell laminated in order of a high distortion point glass substrate, an alkali control layer, a back electrode layer, a p-type CIS-based light absorbing layer, and an n-type transparent conductive film,
wherein said alkali control layer is a silica film whose film thickness is within a range of 2.00-10.00 nm and whose refractive index is within a range of 1.450-1.500.

2. A CIS-based thin film solar cell according to claim 1, wherein the film thickness of said alkali control layer is within a range of 2.00-7.00 nm.

3. A CIS-based thin film solar cell according to claim 1, wherein the refractive index of said alkali control layer is within a range of 1.470-1.490.

4. A CIS-based thin film solar cell according to claim 1, wherein a distortion point of said high distortion point glass substrate is 560° C. or higher.

5. A CIS-based thin film solar cell according to claim 1, wherein an annealing point of said high distortion point glass substrate is 610° C. or higher.

6. A CIS-based thin film solar cell according to claim 1, wherein a thermal expansion coefficient of said high distortion point glass substrate is within a range of 8×10⁻⁶/° C.-9×10⁻⁶/° C.

7. A CIS-based thin film solar cell according to claim 1, wherein a density of said high distortion point glass substrate is within a range of 2.7-2.9 g/cm³.

8. A CIS-based thin film solar cell according to claim 1, characterized in that wherein said high distortion point glass contains 1-7 weight % of Na₂O.

9. A CIS-based thin film solar cell according to claim 8, characterized in that wherein said high distortion point glass contains 3-5 weight % of Na₂O.

10. A CIS-based thin film solar cell according to claim 1, wherein said high distortion point glass contains 1-15 weight % of K₂O.

11. A CIS-based thin film solar cell according to claim 10, wherein said high distortion point glass contains 5-10 weight % of K₂O.

12. A CIS-based thin film solar cell according to claim 1, wherein said high distortion point glass contains 1-15 weight % of CaO.

13. A CIS-based thin film solar cell according to claim 12, wherein said high distortion point glass contains 1-10 weight % of CaO.

14. A CIS-based thin film solar cell according to claim 1, wherein said p-type CIS-based light absorbing layer is formed of a five component compound that comprises Cu, In, Ga, Se and S.

15. A CIS-based thin film solar cell according to claim 14, wherein said p-type CIS-based light absorbing layer is formed by selenizing and sulfurizing a laminated structure containing Cu, In and Ga or a mixed crystal thereof.
